(19) United States
(12) Patent Application Publication
(10) Pub. No.: US 2025/0204035 A1
(43) Pub. Date: Jun. 19, 2025

(54) INTEGRATED CIRCUIT DEVICE WITH DIELECTRIC CUT AT N-P BOUNDARY

(71) Applicant: Intel Corporation, Santa Clara, CA (US)

(72) Inventors: Yang Zhang, Rio Rancho, NM (US); Guowei Xu, Portland, OR (US); Tao Chu, Portland, OR (US); Robin Chao, Portland, OR (US); Chiao-Ti Huang, Portland, OR (US); Feng Zhang, Hillsboro, OR (US); Ting-Hsiang Hung, Beaverton, OR (US); Chia-Ching Lin, Portland, OR (US); Kan Zhang, HILLSBORO, OR (US); Anand S. Murthy, Portland, OR (US)

(73) Assignee: Intel Corporation, Santa Clara, CA (US)

(21) Appl. No.: 18/541,425

(22) Filed: Dec. 15, 2023

(51) Int. Cl. H01L 27/092; H01L 21/8238

(52) U.S. Cl. CPC H10D 84/85; H10D 84/0188; H10D 84/038

(57) ABSTRACT

An IC device may have an N-type transistor and a P-type transistor. The gate of the two transistors may contact and form an N-P boundary. A dielectric cut may be formed at the N-P boundary to reduce the N-P boundary effect in the IC device. The channel region of the N-type transistor may include one or more semiconductor structures, each of which is at least partially surrounded by a first dielectric structure. The channel region of the P-type transistor may include one or more semiconductor structures, each of which is at least partially surrounded by a second dielectric structure. The first dielectric structure and the second dielectric structure may include one or more high-k dielectric materials. A cut may be formed between the first dielectric structure and the second dielectric structure and filled with a low-k dielectric material to mitigate exchange of vacancies between the two transistors.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned in a wafer. The physical layout of the semiconductor devices or their proximity to each other may impact the electrical characteristics of the semiconductor devices. For instance, the boundary effect due to different types of transistors contacting each other can negatively impact the threshold voltages of the transistors. In the BEOL, metal layers, vias, and insulating layers can be formed to get the individual components interconnected. Metal layers can be arranged at both the frontside and the backside of the semiconductor devices. The metal layer that is the closest to the semiconductor devices is often called M0. More metal layers can be formed on top of M0, and these metal layers are often called M1, M2, and so on.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device comprising an FEOL section and a BEOL section, according to some embodiments of the disclosure.

FIG. 2 illustrates an IC device with N-P boundary effect, according to some embodiments of the disclosure.

FIG. 3 illustrates vacancy diffusion at an N-P boundary, according to some embodiments of the disclosure.

FIG. 4 illustrates an IC device with a dielectric cut at an N-P boundary, according to some embodiments of the disclosure.

FIGS. 5A-5E illustrate a process of fabricating an IC device with a dielectric cut at an N-P boundary, according to some embodiments of the disclosure.

FIGS. 6A-6G illustrate another process of fabricating an IC device with a dielectric cut at an N-P boundary, according to some embodiments of the disclosure.

FIGS. 7A-7B are top views of a wafer and dies, according to some embodiments of the disclosure.

FIG. 8 is a side, cross-sectional view of an example IC package that may include one or more IC devices with dielectric cuts at N-P boundaries, according to some embodiments of the disclosure.

FIG. 9 is a cross-sectional side view of an IC device assembly that may include components having one or more IC devices with dielectric cuts at N-P boundaries, according to some embodiments of the disclosure.

FIG. 10 is a block diagram of an example computing device that may include one or more components with dielectric cuts at N-P boundaries, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Many circuit devices include a large array of semiconductor devices, e.g., transistors. Examples of transistors in these circuit devices include metal-oxide-semiconductor field-effect transistor (MOSFET), such as NMOS (N-type metal-oxide-semiconductor) FET (field-effect transistor), PMOS (P-type metal-oxide-semiconductor) FET, and so on. However, the performance of a circuit device can be negatively impacted by local layout effects, i.e., environmental effects that can impact the electrical characteristics of a semiconductor device due to the physical layout of the circuit, such as proximity of the semiconductor device to other features in the circuit. Continued scaling of transistors creates additional challenges, as the scaling of transistors can introduce stronger local layout effects that influence circuit functionality. For instance, local layout effects can influence the threshold voltage (V_{T}) of transistors in a memory device (e.g., a SRAM (static random-access memory)). V_{T} is the required gate voltage to turn on the transistors.

A currently available IC in a memory device may include a plurality of N-P boundaries that can cause significant N-P boundary effect. For instance, an IC device may have a group of N-type transistors over a group of P-type transistors. Each N-type transistor (e.g., an NMOS transistor) contacts a P-type transistor (e.g., a PMOS transistor), e.g., the channel regions (or gates) of the two transistors are connected. As the two transistors have different vacancy concentrations, there can be an exchange of vacancies (e.g., oxygen vacancies) between the two transistors. For example, vacancies can diffuse from the channel region of the N-type transistor to the P-type transistor. With such N-P boundary effect, the transistors can weaken each other and have higher V_{T}. The increase in V_{T} may break the Vₘᵢₙ target in simulation. Additionally, some applications of IC devices require or prefer the IC devices to have low V_{T}.

Embodiments of the present disclosure may improve on at least some of the challenges and issues described above by forming dielectric cuts at N-P boundaries in IC devices. An example IC device may include one or more N-type transistors and one or more P-type transistors. A gate of an N-type transistor and a gate of a P-type transistor may contact each other and form an N-P boundary. High-k dielectric in the two gates may provide a channel for exchange of vacancies (e.g., oxygen vacancies) between the two gates, causing N-P boundary effect in the IC device. A cut may be formed in the high-k dielectric at the N-P boundary and filled with a low-k dielectric to reduce or even eliminate diffusion of vacancies between the two transistors and therefore, reduce or even eliminate the N-P boundary effect.

In various embodiments of the present disclosure, an IC device may have an N-type transistor and a P-type transistor. The channel region of the N-type transistor may include one or more semiconductor structures, each of which may be at least partially surrounded by a first dielectric structure. The channel region of the P-type transistor may include one or more semiconductor structures, each of which may be at least partially surrounded by a second dielectric structure. A semiconductor structure may have a non-planar shape, such as nanoribbon, fin, and so on. The first dielectric structure and the second dielectric structure may include one or more high-k dielectric materials. A high-k dielectric material may have a dielectric constant that is higher than the dielectric constant of silicon dioxide, which may be approximately 3.9. The first dielectric structure and the second dielectric structure are separated. An edge of the first dielectric structure may face an edge of the second dielectric structure. The distance between the two edges may be in a range from approximately 40 nanometers to approximately 50 nanometers. The space between the first dielectric structure and the second dielectric structure is referred to as a dielectric cut or high-k cut. The dielectric cut may be filled with a low-k dielectric material, which may have a dielectric constant that is higher than the dielectric constant of silicon dioxide. A gate electrode of the N-type transistor may be formed over the first dielectric structure and a portion of the dielectric cut. A gate electrode of the P-type transistor may be formed over the first dielectric structure and a portion of the dielectric cut. The two gate electrode may include different work function materials, i.e., materials having different work functions. The two gate electrode may contact each other. The presence of the low-k dielectric material at the N-P boundary can mitigate exchange of vacancies between the two transistors. Compared with conventionally available memory devices, the IC devices in the present disclosure can have lower V_{T} and better performance.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanoribbon” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

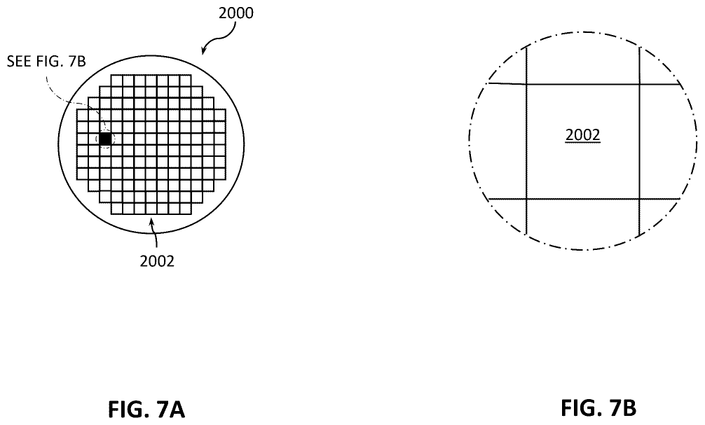

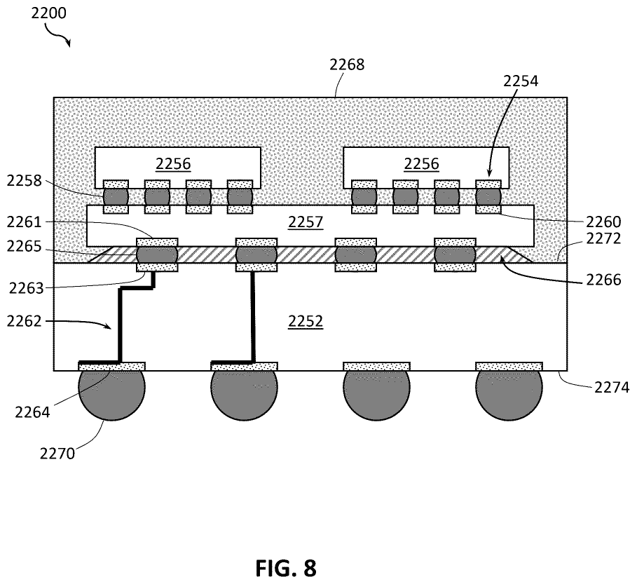

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 8.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of semiconductor devices with dielectric cuts at N-P boundaries as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with dielectric cuts at N-P boundaries as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

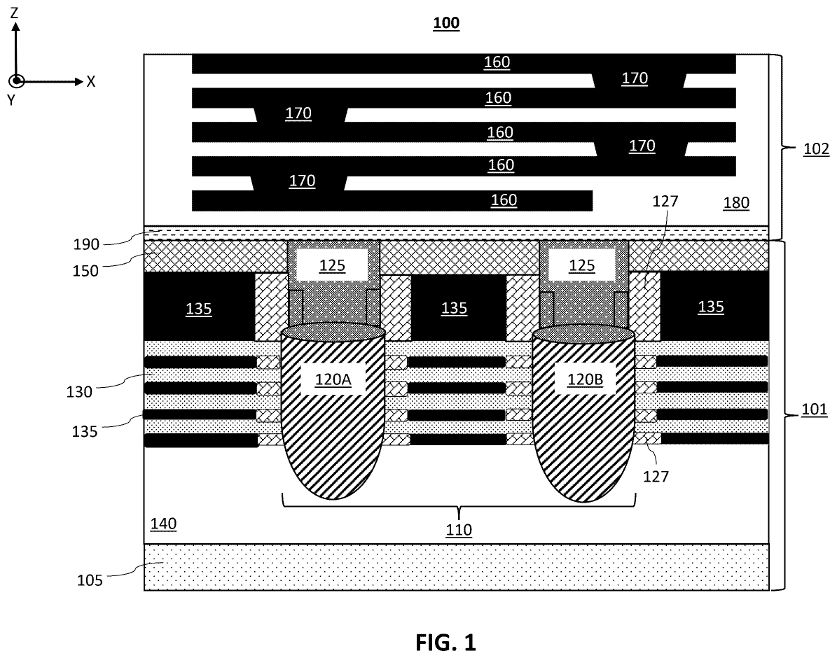

FIG. 1 illustrates an IC device 100 comprising an FEOL section 101 and a BEOL section 102, according to some embodiments of the disclosure. For the purpose of illustration, FIG. 1 shows a cross-sectional view of the IC device 100 in the X-Z plane. The FEOL section 101 includes a support structure 105, semiconductor structures 120A and 120B (collectively referred to as “semiconductor structures 120” or “semiconductor structure 120”), electrodes 125 (individually referred to as “electrode 125”), dielectric structures 127 (individually referred to as “dielectric structure 127”), semiconductor structures 130 (individually referred to as “semiconductor structure 130”), electrodes 135 (individually referred to as “electrode 135”), an electrical insulator 140, and spacers 150 (individually referred to as “spacer 150”). Some of the components in the FEOL section 101 constitute a transistor 110. The BEOL section 102 includes metal layers 160, vias 170, another electrical insulator 180, and a contact layer 190. In other embodiments, the FEOL section 101, the BEOL section 102, or the IC device 100 may include fewer, more, or different components. For example, the IC device 100 may include one or more semiconductor devices not shown in FIG. 1. As another example, the IC device 100 may include a different number of backside semiconductor structures, semiconductor structures, electrodes, metal layers, vias, etc. In some embodiments, the IC device 100 may be formed through a complementary metal-oxide semiconductor (CMOS) fabrication process.

The support structure 105 may be any suitable structure, such as a substrate, a die, a wafer, or a chip. The support structure 105 may, e.g., be the wafer 2000 of FIG. 7A, discussed below, and may be, or be included in, a die, e.g., the singulated die 2002 of FIG. 7B, discussed below. Semiconductor devices may be built over the support structure 105. Examples of the semiconductor devices include transistors (e.g., the transistor 110), resistors, capacitors, and so on. In some embodiments, the support structure 105 may be a semiconductor substrate composed of semiconductor material systems including, for example, N-type or P-type materials systems, and, in some embodiments, the channel region, described herein, may be a part of the support structure 105. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure 105 may be a printed circuit board (PCB) substrate. One or more transistors, such as the transistor may be built on the support structure 105.

Although a few examples of materials from which the support structure 105 may be formed are described here, any material that may serve as a foundation upon which an IC may be built falls within the spirit and scope of the present disclosure. In various embodiments, the support structure 105 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 105 may provide material “support” in that, e.g., the IC devices/structures described herein are build based on the semiconductor materials of the support structure 105. However, in some embodiments, the support structure 105 may provide mechanical support.

The semiconductor structures 120 may have crystal structures. A semiconductor structure 120 may be formed through an epitaxial growth process, in which a crystal material may be formed with one or more well-defined orientations with respect to a crystal substrate after the material is deposited onto the crystal substrate. The semiconductor structures 120 may also be referred to as epitaxial structures or epitaxial semiconductor structures. The crystal substrate used for epitaxial growth may be a die or wafer (not shown in FIG. 1). The crystal direction of the epitaxial structures may be determined based on a crystal direction in the crystal substrate.

The semiconductor structures 130 may be semiconductor structures having non-planar shapes. In the embodiments of FIG. 1, the semiconductor structures 130 are nanoribbons. A semiconductor structure 130 may have a longitudinal axis along the X axis. The semiconductor structure 130 may also have a transverse cross-section that is perpendicular to the longitudinal axis. The transverse cross-section may be in the Y-Z plane. The dimension of the semiconductor structure 120 along the X axis may be greater (e.g., significantly greater) than the dimension of the semiconductor structure 120 along the Y axis or along the Z axis. In other embodiments, the semiconductor structures 130 may have other non-planar shapes, such as fins. In yet other embodiments, the semiconductor structures 130 may be planar structurers.

The semiconductor structures 120 and the semiconductor structures regions 130 may be semiconductor regions in transistors. In an example, the semiconductor structure 120A may constitute a source region of the transistor 110. The semiconductor structure 120B may constitute a drain region of the transistor 110. In another example, the semiconductor structure 120A may be a drain region of the transistor 110, while the semiconductor structure 120B may be a source region of the transistor 110. Portions of the semiconductor structures 130 between the source region and drain region may constitute the channel region of the transistor 110.

A channel region of a transistor may include a channel material. The channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For some example N-type transistor embodiments (i.e., for the embodiments where the transistor 110 is an NMOS transistor or an N-type TFET), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 1015 dopant atoms per cubic centimeter (cm-3), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where the transistor 110 is a PMOS transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more nominal impurity dopant levels may be present within the channel material, for example to further set a threshold voltage (Vt), or to provide HALO pocket implants, etc. Even for impurity-doped embodiments however, impurity dopant level within the channel portion is relatively low, for example below 1015 cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminium zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminium gallium nitride, indium phosphite, black phosphorus, zinc sulfide, indium sulfide, gallium sulfide, each of which may possibly be doped with one or more of gallium, indium, aluminium, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminium or nitrogen.

The source region and the drain region are connected to the channel region. The source region and the drain region each include a semiconductor material with dopants. In some embodiments, the source region and the drain region have the same semiconductor material, which may be the same as the channel material of the channel region. A semiconductor material of the source region or the drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminium (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (Cl), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region and the drain region may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region, and, therefore, may be referred to as “highly doped” (HD) regions.

The channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

The two electrodes 125 are over the two semiconductor structures 120, respectively. Each electrode 125 may be a source electrode or a drain electrode of a transistor. A source electrode is an electrode over a source region. A drain electrode is an electrode over a drain region. The electrode 125 may be coupled to a power source for delivering power to the source or drain region. In some embodiments, the electrodes 125 may be at different electrical potentials during the operation of the IC device. One of the electrodes 125 may be coupled to a power plane, and the other one of the electrodes 125 may be coupled to a ground plane. Each electrode 125 includes one or more electrically conductive materials, such as metals. Examples of metals in the electrode 145A and the electrode 145B may include, but are not limited to, ruthenium (Ru), copper (Cu), cobalt (Co), palladium (Pd), platinum (Pt), nickel (Ni), and so on.

The electrodes 135 may be gate electrodes of transistors. An electrode 135 may be over a channel region of a transistor. A transistor also includes a gate insulator. An electrode 135 and the gate insulator may constitute a gate that is over or wraps around at least a portion of the channel region. The gate electrode can be coupled to a gate terminal that controls gate voltages applied on the transistor 110. The gate electrode may include one or more gate electrode materials, where the choice of the gate electrode materials may depend on whether the transistor 110 is a P-type transistor or an N-type transistor. For a P-type transistor, gate electrode materials that may be used in different portions of the gate electrode may include, but are not limited to, metal (e.g., ruthenium, palladium, platinum, cobalt, nickel, etc.), conductive metal oxides (e.g., ruthenium oxide, etc.), other types of conductive materials, or some combination thereof. For an N-type transistor, gate electrode materials that may be used in different portions of the gate electrode, but are not limited to, hafnium, zirconium, titanium, tantalum, aluminium, alloys of these metals, and carbides of these metals (e.g., hafnium carbide, zirconium carbide, titanium carbide, tantalum carbide, and aluminium carbide). In some embodiments, the gate electrode may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. In some embodiments, the gate electrodes of transistors of different types may have different work function materials. For instance, one or more work function materials in the gate electrode of an N-type transistor are different from one or more work function materials in the gate electrode of a P-type transistor.

The gate insulator separates at least a portion of the channel region from the gate electrode so that the channel region is insulated from the gate electrode. In some embodiments, the gate insulator may wrap around at least a portion of the channel region. The gate insulator may also wrap around at least a portion of the source region or the drain region. At least a portion of the gate insulator may be wrapped around by the gate electrode. The gate insulator includes an electrical insulator, such as a dielectric material, hysteretic material, and so on. Examples of dielectric materials include oxide (e.g., silicon-based oxides, metal oxides, etc.), nitride, carbide, and so on. Examples of hysteretic materials include ferroelectric materials, antiferroelectric materials, etc.

In some embodiments, the dielectric structures 127 constitute gate insulators. The dielectric structures 127 may be electrically insulative. A dielectric structure 127 may surround at least part of a semiconductor structure 130. The dielectric structure 127 may separate the semiconductor structure 130 from the corresponding gate electrode. A dielectric structure 127 may include one or more high-k dielectric materials. A high-k dielectric material may have dielectric constants higher than the dielectric constant of silicon dioxide. The dielectric constant of silicon dioxide may be approximately 3.9. Examples of high-k dielectric materials include aluminium oxide, zirconium dioxide, hafnium (IV) oxide, silicon nitride, tantalum pentoxide, lead zirconate titanate, and so on.

The electrical insulator 140 and spacers 150 are also electrically insulative and may include electrical insulators, such as the ones described above. The electrical insulator 140 and spacers 150 may separate components in the IC device 100 from each other so that these components are not undesirably coupled to each other. For instance, the electrical insulator 140 may separate some of the electrodes 135 from the support structure 105. The spacers 150 may separate some or all of the electrodes 135 from the semiconductor structures 120. The spacers 150 may also separate some or all of the electrodes 135 from some or all of the electrodes 125. Also, the spacer 150 may insulate some or all of the electrodes 135 from other components in the IC device 100, e.g., the electrodes 125, the contact layer 190, and so on. In some embodiments, a dielectric structure 127, the electrical insulator 140, and the spacer 150 includes one or more insulating materials, such as the electrical insulators described above.

In some embodiments, a spacer 150 may include a dielectric material that is different from the dielectric material(s) in the dielectric structures 127. In an example, a spacer 150 may include one or more low-k dielectric materials. A low-k dielectric material may have dielectric constants lower than the dielectric constant of silicon dioxide. Examples of low-k dielectric materials include silicon-based low-k materials (e.g., fluorine doped silicon dioxide, carbon-doped silicon oxide, silicon oxycarbides, etc.), polymers, silsesquioxane (SSQ)-based materials (e.g., hydrogen-SSQ, methyl-SSQ, etc.), and so on.

Even though FIG. 1 shows a single transistor, the IC device 100 may include one or more other transistors. Examples of transistors in the IC device 100 may include FET, such as metal-oxide-semiconductor FET (MOSFET), tunnel FET (TFET), fin-based transistor (e.g., FinFET), nanoribbon-based transistor, gate-all-around (GAA) transistor, other types of FET, or some combination thereof. In some embodiments, the IC device 100 may include one or more N-type transistors (e.g., NMOS transistors) and one or more P-type transistors (e.g., PMOS transistors). For instance, the IC device 100 may include another transistor that is arranged over the transistor 110 along the Y axis. The other transistor may be of the opposite type from the transistor 110. In an example, the transistor 110 may be an N-type transistor, while the other transistor is a P-type transistor. In another example, the transistor 110 may be a P-type transistor, while the other transistor is an N-type transistor. The gate electrode of the transistor 110 may include a different work function material from the gate electrode of the other transistor. The gate electrode of the two transistors may contact each other.

The metal layers 160 are stacked over the support structure 105 and transistors (e.g., the transistor 110) along the Z axis. In some embodiments, the metal layers 160 are frontside metal layers that are arranged at the frontside of the support structure 105. The IC device 100 may also include one or more backside metal layers (not shown in FIG. 1) at the backside of the support structure 105. A metal layer 160 may include one or more metal lines, which is also referred to as interconnects. A metal line may have a longitudinal axis, which may be along the X axis or Y axis. In some embodiments, the metal lines in the same metal layer 160 may be in parallel. The metal lines in two adjacent metal layers may be perpendicular to each other. A metal layer 160 may provide power or signal to an electrode 125 or 135 of the transistor 110. The metal layers 160 may be coupled with other devices than the transistor 110, such as diodes, power sources, resistors, capacitors, inductors, sensors, transceivers, receivers, antennas, and so on. The metal layers 160 may be used to deliver power or signal to such devices.

As shown in FIG. 1, the metal layers 160 may be coupled to each other using the vias 170. A via 170 may be connected to two or more metal layers 160 and have a longitudinal axis perpendicular to the metal layers 160. The electrical connections between the metal layers 160 may be different from the electrical connections shown in FIG. 1. Also, even though not shown in FIG. 1, the IC device 100 may include other vias that couple one or more metal layers 160 to one or more of the electrodes 125 and 135. The electrical insulator 180 surrounds the metal layers 160 and vias 170. The electrical insulator 180 may include one or more electrically insulating materials, such as a dielectric material, hysteretic material, and so on. The metal layer 160 that is closest to the support structure 105 may be referred to as M0, the next metal layer 160 may be referred to as M1, and so on.

The contact layer 190 may facilitate bonding or coupling of the BEOL section 102 of the IC device 100 with the rest of the IC device 100. The contact layer 190 may include a bonding material, e.g., glue. In some embodiments, the contact layer 190 may include one or more electrically conductive structures for coupling one or more metal layers 160 to other components of the IC device, such as one or more electrodes 125 and 135.

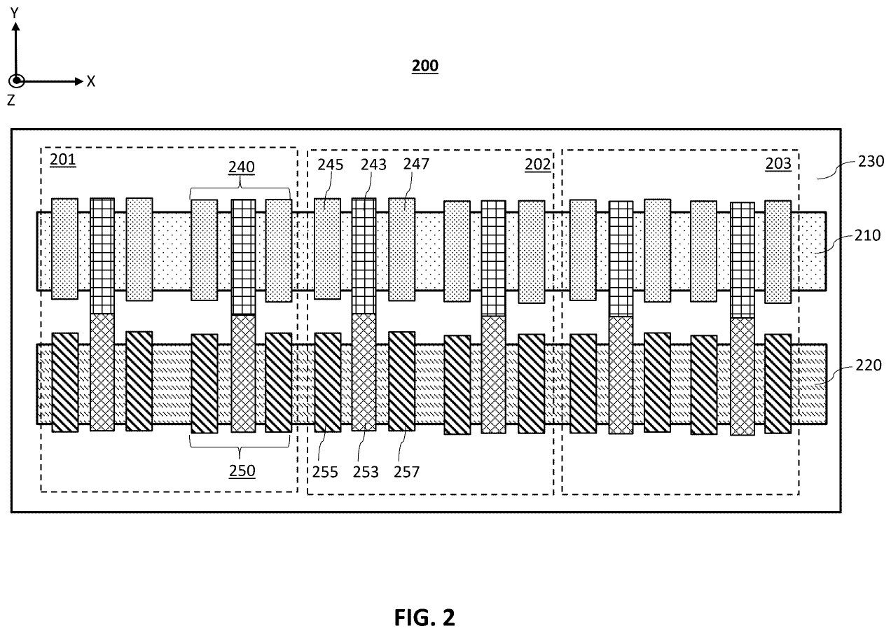

FIG. 2 illustrates an IC device 200 with N-P boundary effect, according to some embodiments of the disclosure. The IC device 200 includes a support structure 210, another support structure 220, an electrical insulator 230, a sequence of transistors 240 (individually referred to as “transistor 240”) associated with the support structure 210, and a sequence of transistors 250 (individually referred to as “transistor 250”) associated with the support structure 220. In other embodiments, the IC device 200 may include fewer, more, or different components. In some embodiments, the IC device 200 may be used in a memory device, such as SRAM, DRAM, etc. In other embodiments, the IC device 200 may be used in a logic device. An example of the IC device 200 may be the IC device 100 in FIG. 1. An example of the transistors 240 and 250 may be the transistor 110.

The support structure 210 or 220 may include one or more semiconductor materials. In some embodiments, the support structure 210 or 220 may be a semiconductor substrate based on which the transistors 240 or 250 can be formed. In some embodiments, the support structures 210 and 220 may include opposite types of semiconductors. For instance, the support structure 210 may be an N-type semiconductor substrate, while the support structure 210 may be a P-type semiconductor substrate. The support structure 210 or 220 may be an embodiment of the support structure 105 in FIG. 1.

The support structures 210 and 220 (or the transistors 240 and 250) may be partially or wholly surrounded by the electrical insulator 230. The electrical insulator 230 may separate and insulate semiconductor components or conductive components in the support structures 210 and 220 (or the transistors 240 and 250). The electrical insulator 230 may include one or more electrical insulative materials, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

A transistor 240 or 250 may be a MOSFET, such as P-MOSFET or N-MOSFET. In some embodiments, the transistors 240 may be the same type of transistor as each other, and the transistors 250 may be the same type of transistor as each other. The transistors 240 may be of the opposite type from the transistors 250. For instance, the transistors 240 may be P-type transistors, while the transistors 250 may be N-type transistors. Each transistor 240 includes a gate 243, a source region 245, and a drain region 247. Even though FIG. 2 shows six transistors 240 and six transistors 250, the IC device 200 may include a different number of transistors 240 or 250. In some embodiments, the IC device 200 may include two pass-gate sections 201 and 203 and a pull-down section 202. The pull-down section 202 is between the two pass-gate sections 201 and 203. Each of these sections is represented by a dashed rectangular in FIG. 2. The pass-gate section 201 includes two transistors 240 and two transistors 250, and these four transistors may be pass-gate transistors. Similarly, the pass-gate section 203 includes two transistors 240 and two transistors 250, and these four transistors may be pass-gate transistors. The pull-down section 202 includes two transistors 240 and two transistors 250, and these four transistors may be pull-down transistors.

In some embodiments (e.g., embodiments where each transistor 240 is a P-type transistor), the gate 243 may include one or more P-type gate electrodes. The gate 243 may also include a gate insulator. The source region 245 and drain region 246 may include one or more P-type semiconductor materials. Even though now shown in FIG. 2, a transistor 240 also includes a channel region between the source region 245 and drain region 246. The channel region may be the portion of the support structure 210, which may be an N-type semiconductor substrate. The channel region may be over the gate 243, e.g., along a Z axis that is perpendicular to the X-Y plane. The channel region may be at least partially wrapped by the gate insulator in the gate 243.

In some embodiments (e.g., embodiments where each transistor 250 is an N-type transistor), the gate 253 may include one or more N-type gate electrodes. The gate 253 may also include a gate insulator. The source region 255 and drain region 256 may include one or more N-type semiconductor materials. Even though now shown in FIG. 2, a transistor 250 also includes a channel region between the source region 255 and drain region 256. The channel region may be the portion of the support structure 220, which may be a P-type semiconductor substrate. The channel region may be over the gate 253, e.g., along a Z axis that is perpendicular to the X-Y plane.

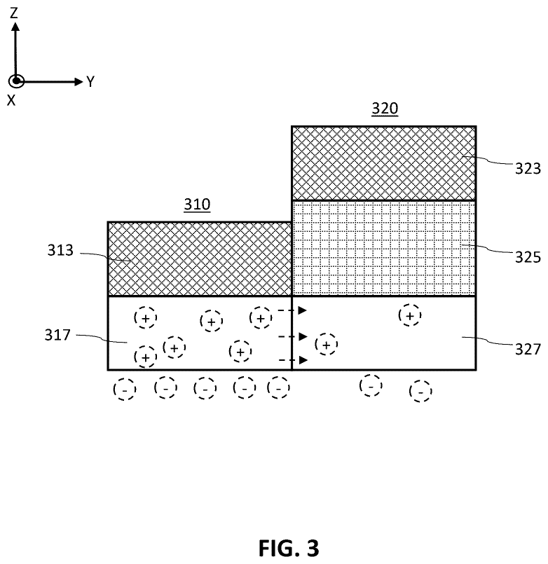

As shown in FIG. 2, each gate 243 contacts a gate 253. The contact of the gate 243 and the gate 253 may cause N-P boundary effect (such as the N-P boundary effect described below in conjunction with FIG. 3) in the IC device 200. As every transistor 240 contacts a transistor 250, the N-P boundary effect can be significant, resulting in undesirable increase in the threshold voltages of the transistors 240, transistors 250, or both.

FIG. 3 illustrates vacancy diffusion at an N-P boundary, according to some embodiments of the disclosure. FIG. 3 shows two gates 310 and 330. In some embodiments, the gate 310 is a gate of an N-type transistor, such as an NMOS transistor. The gate 310 may be referred to as an N-type gate. The gate 310 includes a conductive structure 313 and an insulative structure 317. The conductive structure 313 may be the gate electrode, which may be an example of the electrodes 135 in FIG. 1. The insulative structure 317 may be the gate insulator. The gate 320 is a gate of a P-type transistor, such as a PMOS transistor. The gate 320 may be referred to as a P-type gate. The gate 320 includes conductive structures 323 and 325 and an insulative structure 327. The conductive structures 323 and 325 may constitute the gate electrode, which may be an example of the electrodes 135 in FIG. 1. The insulative structure 327 may be the gate insulator. In other embodiments, the gate 310 or 320 may include fewer, more, or different components.

The conductive structure 313 may include the same conductive material as the conductive structure 323. In an example, the conductive material may be titanium aluminium carbide. The conductive structure 313 or 323 may have a thickness along the Z axis in a range from approximately 3 nm to 5 nm. In other embodiments, the conductive structure 313 or 323 may include one or more different materials or have a different thickness. The conductive structure 325 may include a different conductive material from the conductive structure 313 or 323. For instance, the conductive material in the conductive structure 325 may have a different work function from the conductive material in the conductive structure 313 or 323. In an example, the conductive structure 325 may include titanium nitride.

The insulative structure 317 or 327 includes one or dielectric materials, such as high-k dielectrics. In some embodiments, the insulative structures 317 and 327 may include the same dielectric material. Each of the insulative structures 317 and 327 has vacancies with positive polarity. The vacancies may include oxygen vacancies, hydrogen vacancies, other vacancies, or some combination thereof. However, the insulative structure 317 has more vacancies than the insulative structure 327, as the gate 310 is in an N-type transistor versus the gate 320 is in a P-type transistor. The concentration of vacancies (e.g., the number of vacancies in a unit volume) in the insulative structure 317 may also be higher than the concentration of vacancies in the insulative structure 327. Given the difference in the number or concentration of vacancies in the insulative structures 317 and 327, the vacancies may move from the insulative structure 317 into the insulative structure 327, as illustrated by the arrows in FIG. 3. Such vacancy diffusion constitutes N-P boundary effect that causes the insulative structures 317 to have less vacancies and the insulative structures 327 to have more vacancies. As a result, the positive polarity in the gate 310 and the negative polarity in the gate 320 are both weakened. Thus, the N-P boundary effect can result in higher threshold voltages for both transistors.

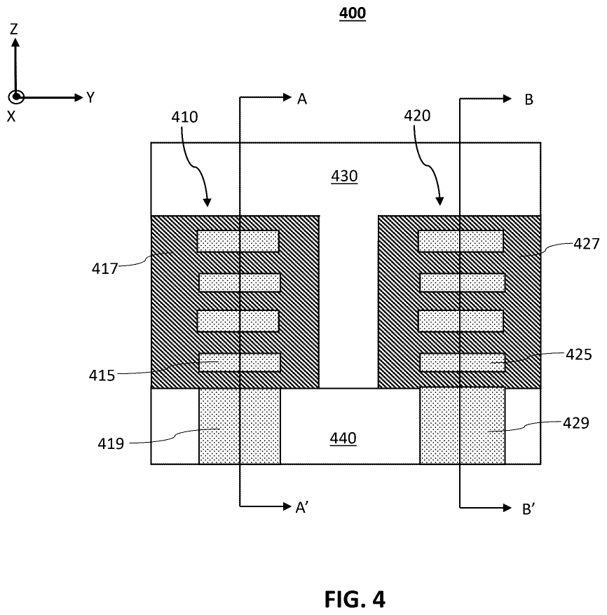

FIG. 4 illustrates an IC device 400 with a dielectric cut at an N-P boundary, according to some embodiments of the disclosure. The IC device 400 may be an example of the IC device 100 in FIG. 1. As shown in FIG. 4, the IC device 400 includes an N-type transistor 410 and a P-type transistor 420. The N-type transistor 410 includes semiconductor structures 415 (individual referred to as “semiconductor structure 415”), a dielectric structure 417, and another semiconductor structure 419. The P-type transistor 420 includes semiconductor structures 425 (individual referred to as “semiconductor structure 425”), a dielectric structure 427, and another semiconductor structure 429. The dielectric cut may be the space between the dielectric structure 417 and the dielectric structure 427. The IC device 400 also includes an electrical insulator 430 and another electrical insulator 440.

The semiconductor structures 415 may be non-planar semiconductor structures, such as nanoribbons. The semiconductor structures 415 are surrounded by the dielectric structure 417. The dielectric structure 417 may include a high-k dielectric material. The semiconductor structure 419 may be a sub-fin. In some embodiments, the semiconductor structure 419 may have the same semiconductor material(s) as the semiconductor structures 415. The semiconductor structure 419 is surrounded by the electrical insulator 440. The electrical insulator 440 may include one or more electrically insulating materials, such as the ones described above.

The semiconductor structures 425 may be non-planar semiconductor structures, such as nanoribbons. The semiconductor structures 425 are surrounded by the dielectric structure 427. The dielectric structure 427 may include a high-k dielectric material. The semiconductor structure 429 may be a sub-fin. In some embodiments, the semiconductor structure 429 may have the same semiconductor material(s) as the semiconductor structures 425. The semiconductor structure 429 is surrounded by the electrical insulator 440.

FIG. 4 indicates two cross-sections of the IC device 400 in X-Z planes: A-A′ and B′B′. An example of a cross-sectional view of the IC device 400 at the A-A′ cross-section or at the B-B′ cross-section may be the view of the IC device 100 shown in FIG. 1. For the purpose of illustration and simplicity, some components of the IC device 400 are not shown in FIG. 4. For instance, the N-type transistor 410 may include other components not shown in FIG. 4, such as a source region, a drain region, a source electrode, a drain electrode, and one or more gate electrodes. The P-type transistor 420 may include other components not shown in FIG. 4, such as a source region, a drain region, a source electrode, a drain electrode, and one or more gate electrodes.

In some embodiments, at least part of a gate electrode of the N-type transistor 410 may be arranged over the dielectric structure 417, e.g., in a direction along the X axis. Also, at least part of the gate electrode of the P-type transistor 420 may be arranged over the dielectric structure 427, e.g., in a direction along the X axis. A part of the gate electrode of the N-type transistor 410 may be over a portion of the dielectric cut, and a part of the gate electrode of the P-type transistor 420 may be over another portion of the dielectric cut. The gate electrode of the N-type transistor 410 may contact the gate electrode of the P-type transistor 420. In an example, the two gate electrodes may have a boundary in an X-Z plane. The boundary between the gate electrode of the N-type transistor 410 and the gate electrode of the P-type transistor 420 may constitute at least part of the N-P boundary between the N-type transistor 410 and the P-type transistor 420.

The dielectric cut between the dielectric structure 417 and the dielectric structure 427 can mitigate the N-P boundary effect. In the embodiments of FIG. 4, the dielectric cut is filled with the electrical insulator 430, which separates the dielectric structure 417 from the dielectric structure 427. The electrical insulator 430 may include a low-k material. The presence of the electrical insulator 430 between the dielectric structure 417 and the dielectric structure 427 can mitigate vacancy diffusion at the N-P boundary (e.g., the vacancy diffusion shown in FIG. 3). The electrical insulator 430 is also present over the dielectric structure 417 and the dielectric structure 427 along the Z axis. The electrical insulator 430 can separate the dielectric structure 417 and the dielectric structure 427 from other components of the transistors 410 and 420 or other components of the IC device 400.

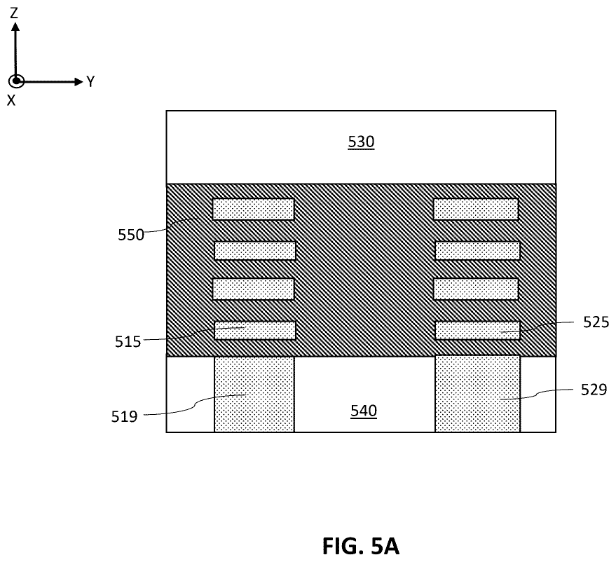

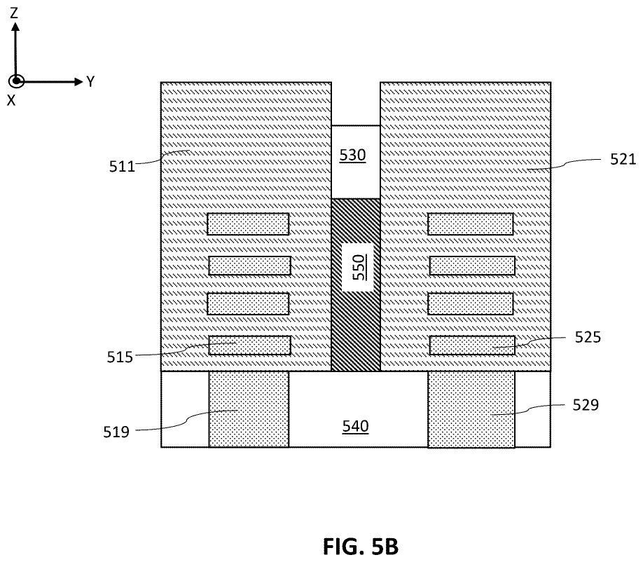

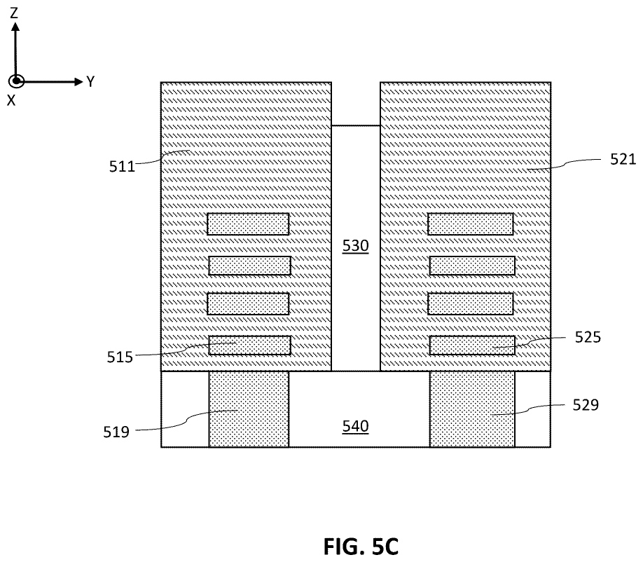

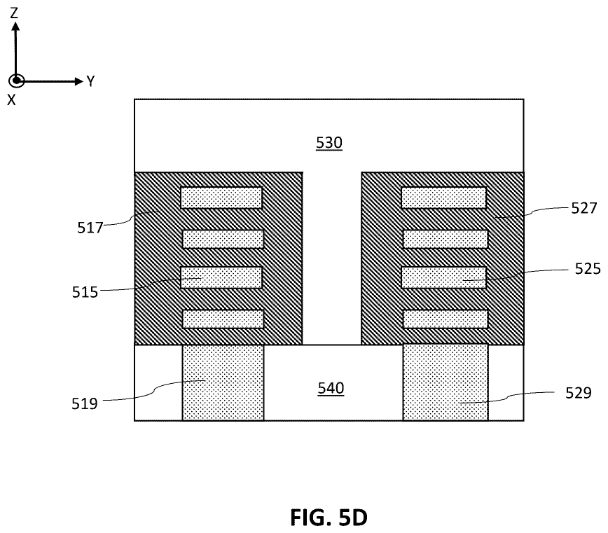

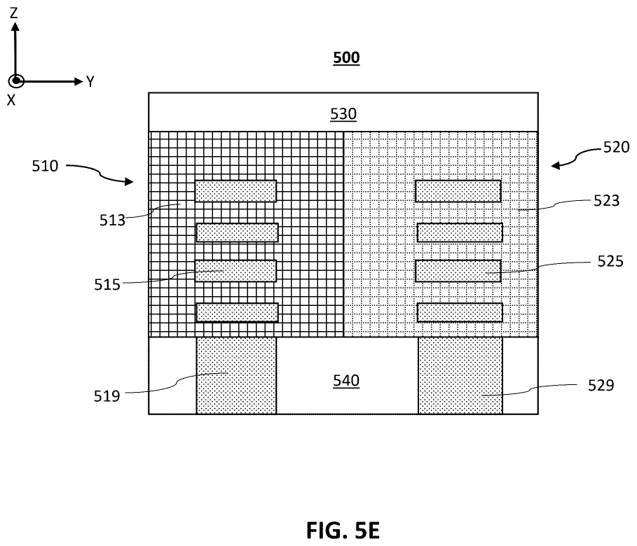

FIGS. 5A-5E illustrate a process of fabricating an IC device 500 with a dielectric cut at an N-P boundary, according to some embodiments of the disclosure. The IC device 500 may be an example of the IC device 100 in FIG. 1 or the IC device 400 in FIG. 4. Although the process is described with reference to the steps shown in FIGS. 5A-5E, many other processes for fabricating IC devices with dielectric cuts may alternatively be used. For example, the order of execution of the steps shown in FIGS. 5A-5E may be changed. As another example, some of the steps may be changed, eliminated, or combined.

FIG. 5A shows a group of semiconductor structures 515 (individual referred to as “semiconductor structure 515”), a group of semiconductor structures 525 (individual referred to as “semiconductor structure 525”), a semiconductor structure 519, another semiconductor structure 529, an electrical insulator 530, another electrical insulator 540, and a dielectric structure 550. The semiconductor structures 515 may be a channel region of a transistor. The semiconductor structures 525 may be a channel region of another transistor. The semiconductor structures 515 may have a semiconductor material that is of an opposite type of a semiconductor material in the semiconductor structures 525. In an example, the semiconductor structures 515 includes a N-type semiconductor material, while the semiconductor structures 525 includes a P-type semiconductor material. In another example, the semiconductor structures 515 includes a P-type semiconductor material, while the semiconductor structures 525 includes a N-type semiconductor material. In some embodiments, the semiconductor structures 515 and 525 may be non-planar semiconductor structures, such as nanoribbons. The semiconductor structures 515 and 525 are surrounded by the dielectric structure 550. The dielectric structure 550 may include a high-k dielectric material.

The semiconductor structures 519 and 529 may each be a sub-fin. In some embodiments, the semiconductor structure 519 may have the same semiconductor material(s) as the semiconductor structures 515. The semiconductor structure 529 may have the same semiconductor material(s) as the semiconductor structures 525. The semiconductor structures 519 and 529 are surrounded by the electrical insulator 540. The electrical insulator 530 or 540 may include one or more electrically insulating materials, such as the ones described above. In some embodiments, the electrical insulator 530 may extends to the top edge of the electrical insulator 540. A portion of the electrical insulator 530 may be behind the dielectric structure 550 in a direction along the X axis.

In FIG. 5B, two dielectric structures 511 and 521 are formed. The dielectric structure 511 may be formed by depositing a material over a portion of the electrical insulator 530 and a portion of the dielectric structure 550. The material may include a polymer, an oxide, or other types of insulating materials. The dielectric structure 521 may be formed by depositing the same material or a different material over another portion of the electrical insulator 530 and another portion of dielectric structure 550. There is an opening between the dielectric structures 511 and 521 so the rest of the electrical insulator 530 (i.e., the part of the electrical insulator 530 that is not covered by the dielectric structures 511 and 521) and the rest of the dielectric structure 550 (i.e., the part of the dielectric structure 550 that is not covered by the dielectric structures 511 and 521) are visible in FIG. 5B.

In FIG. 5C, the part of the dielectric structure 550 that is not covered by the dielectric structures 511 and 521 is removed to form a dielectric cut. In embodiments where the dielectric structure 550 includes a high-k dielectric material, the dielectric cut is also referred to as a high-k cut. In some embodiments, the port of the dielectric structure 550 may be removed through an etching process. The part of the electrical insulator 530 that is covered by the removed part of the dielectric structure 550 is visible in FIG. 5C.

In FIG. 5D, the dielectric structures 511 and 521 are removed. In some embodiments, the dielectric structures 511 and 521 may be removed through an ashing process. An example of the ashing process may be plasma ashing, such as oxygen plasma ashing. The unremoved portions of the dielectric structure 550, which become dielectric structures 517 and 527, are visible in FIG. 5D.

In FIG. 5E, gate electrodes 513 and 523 are formed. The gate electrodes 513 and 523 may each include one or more conductive materials, such as metals. The gate electrode 513 is over the dielectric structure 517 along the X axis. The gate electrode 513 surrounds at least part of each semiconductor structure 515. In some embodiments, the gate electrode 513 and the dielectric structure 517 may constitute the gate of a transistor 510 that has the semiconductor structures 515 as its channel region. The gate electrode 523 is over the dielectric structure 527 along the X axis. The gate electrode 523 surrounds at least part of each semiconductor structure 525. The gate electrode 523 and the dielectric structure 527 may constitute the gate of another transistor 520 that has the semiconductor structures 525 as its channel region.

The two transistors 510 and 520 may be of opposite types. In embodiments where the transistor 510 is an N-type transistor and the transistor 520 is a P-type transistor, an example of the gate electrode 513 may be the conductive structure 313 in FIG. 3, and an example of the gate electrode 523 may include the conductive structures 323 and 325 in FIG. 3. In embodiments where the transistor 510 is a P-type transistor and the transistor 520 is an N-type transistor, an example of the gate electrode 513 may include the conductive structures 323 and 325 in FIG. 3, and an example of the gate electrode 523 may be the conductive structure 313 in FIG. 3.

The transistor 510 or 520 may also include a source region and a drain region (not shown in FIG. 5E), and the channel region may be between the source region and drain region in a direction along the X axis. The electrical insulator 530 may separate the gate electrodes 513 and 523 from the corresponding source regions and drain regions. Other components of the transistors 510 and 520 may also be formed.

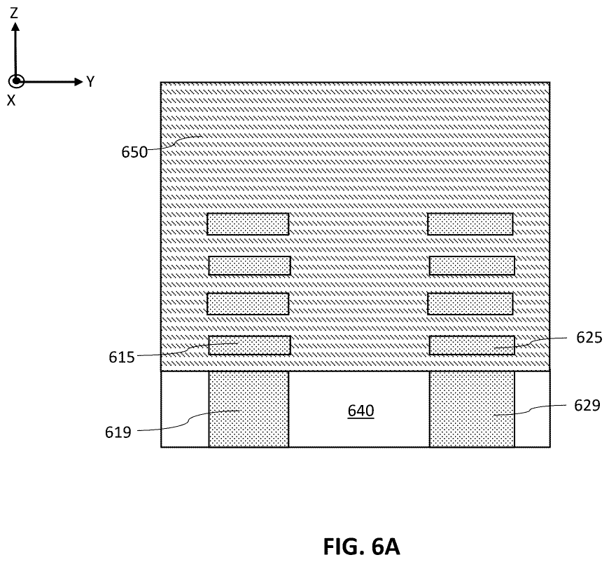

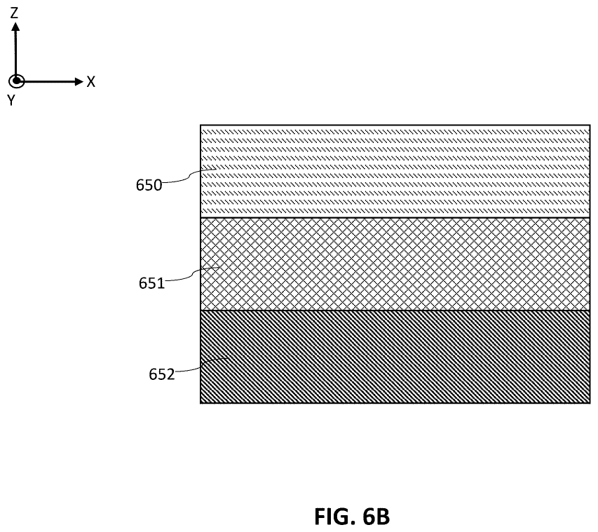

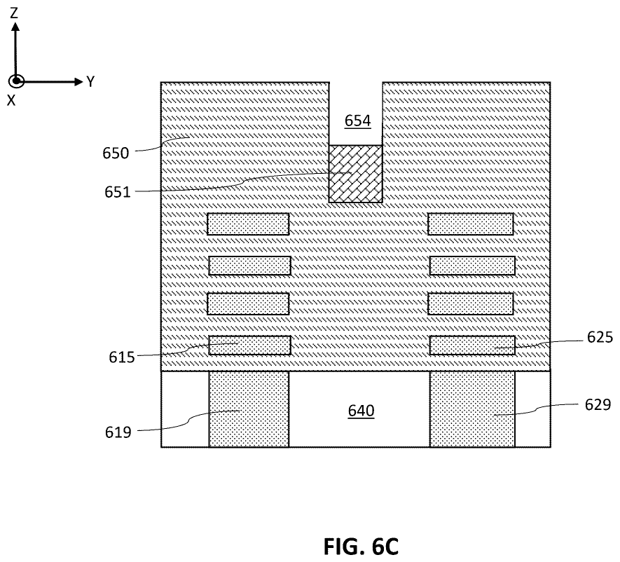

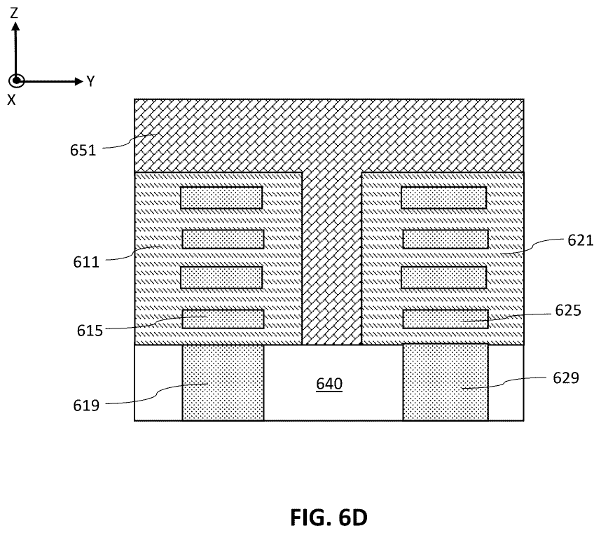

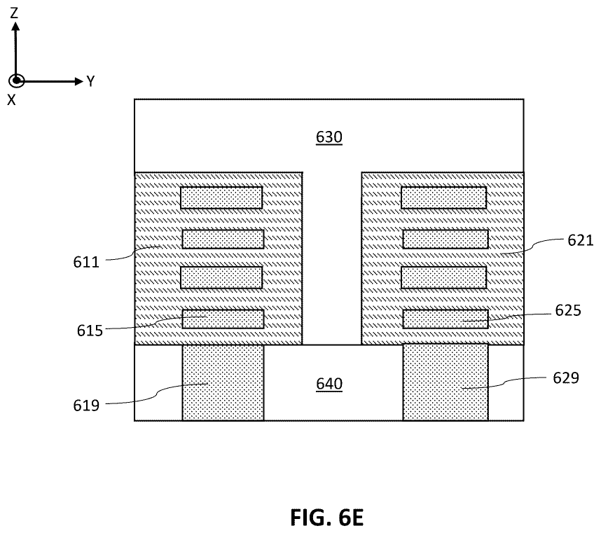

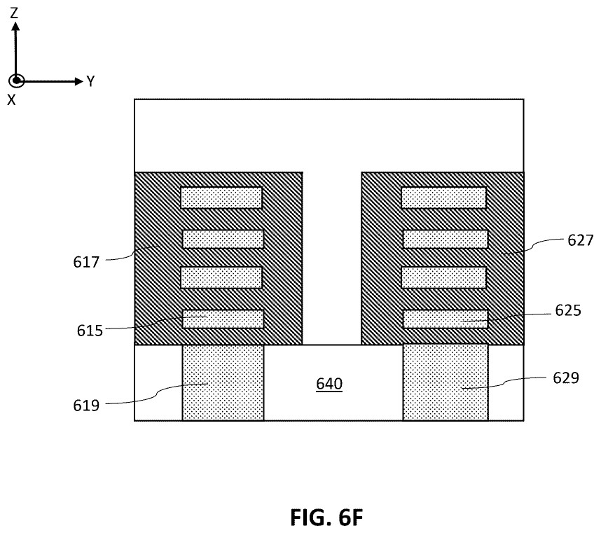

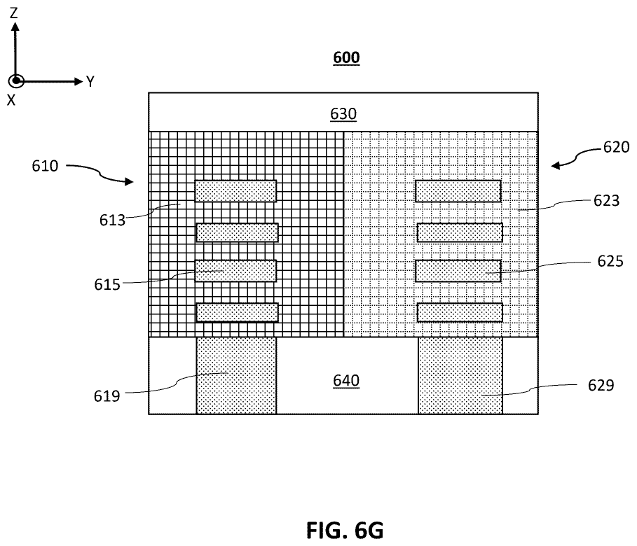

FIGS. 6A-6G illustrate another process of fabricating an IC device 600 with a dielectric cut at an N-P boundary, according to some embodiments of the disclosure. The IC device 600 may be an example of the IC device 100 in FIG. 1 or the IC device 400 in FIG. 4. Although the process is described with reference to the steps shown in FIGS. 6A-6G, many other processes for fabricating IC devices with dielectric cuts may alternatively be used. For example, the order of execution of the steps shown in FIGS. 6A-6G may be changed. As another example, some of the steps may be changed, eliminated, or combined.

FIG. 6A shows a group of semiconductor structures 615 (individual referred to as “semiconductor structure 615”), a group of semiconductor structures 625 (individual referred to as “semiconductor structure 625”), a semiconductor structure 619, another semiconductor structure 629, an electrical insulator 640, and a dielectric structure 650. The semiconductor structures 615 may be a channel region of a transistor. The semiconductor structures 625 may be a channel region of another transistor. The semiconductor structures 615 may have a semiconductor material that is of an opposite type of a semiconductor material in the semiconductor structures 625. In an example, the semiconductor structures 615 includes a N-type semiconductor material, while the semiconductor structures 625 includes a P-type semiconductor material. In another example, the semiconductor structures 615 includes a P-type semiconductor material, while the semiconductor structures 625 includes a N-type semiconductor material. In some embodiments, the semiconductor structures 615 and 625 may be non-planar semiconductor structures, such as nanoribbons. The semiconductor structures 615 and 625 are surrounded by the dielectric structure 650. The dielectric structure 650 may include a dielectric material, such as a polymeric material, an oxide, etc.

The semiconductor structures 619 and 629 may each be a sub-fin. In some embodiments, the semiconductor structure 619 may have the same semiconductor material(s) as the semiconductor structures 615. The semiconductor structure 629 may have the same semiconductor material(s) as the semiconductor structures 625. The semiconductor structures 619 and 629 are surrounded by the electrical insulator 640. The electrical insulator 640 may include one or more electrically insulating materials, such as the ones described above.

In some embodiments, a part of the dielectric structure 650 is over a structure 651 and another structure 652 along the X axis, as shown in FIG. 6B. In some embodiments, the structure 651 may be a hard mask. The structure 651 may include titanium nitride. The structure 652 may be a dielectric structure including a high-k dielectric material.

In FIG. 6C, a portion of the dielectric structure 650 is removed, forming an opening region 654 and exposing a portion of the structure 651. The portion of the dielectric structure 650 may be removed through ashing. The opening region 654 is between the group of semiconductor structures 615 and the group of semiconductor structure 625 along the Y axis.

In FIG. 6D, another portion of the dielectric structure 650 is removed, e.g., through ashing. The remaining portions of the dielectric structure 650 constitute two separate dielectric structures 611 and 621. There is an opening between the dielectric structures 611 and 621 so a portion of the structure 651 (i.e., the portion of the structure 651 that is not covered by the dielectric structures 611 and 621) is visible in FIG. 6D.

In FIG. 6E, the rest of the structure 651 is removed, e.g., through etching or polishing. Also, the part of the structure 652 that is not covered by the dielectric structures 611 and 621 is removed to form a dielectric cut. In embodiments where the dielectric structure 650 includes a high-k dielectric material, the dielectric cut is also referred to as a high-k cut. In some embodiments, the port of the dielectric structure 650 may be removed through an etching process. An electrical insulator 630 is provided to fill the dielectric cut. The electrical insulator 630 is also provided over the dielectric structures 611 and 621 along the Z axis. The electrical insulator 630 may include a low-k dielectric material.

In FIG. 6F, the dielectric structures 611 and 621 are removed. In some embodiments, the dielectric structures 611 and 621 may be removed through an ashing process. An example of the ashing process may be plasma ashing, such as oxygen plasma ashing. The unremoved portions of the dielectric structure 650, which become dielectric structures 617 and 627, are visible in FIG. 6D.

In FIG. 6G, gate electrodes 613 and 623 are formed. The gate electrodes 613 and 623 may each include one or more conductive materials, such as metals. The gate electrode 613 is over the dielectric structure 617 along the X axis. The gate electrode 613 surrounds at least part of each semiconductor structure 615. In some embodiments, the gate electrode 613 and the dielectric structure 617 may constitute the gate of a transistor 610 that has the semiconductor structures 615 as its channel region. The gate electrode 623 is over the dielectric structure 627 along the X axis. The gate electrode 623 surrounds at least part of each semiconductor structure 625. The gate electrode 623 and the dielectric structure 627 may constitute the gate of another transistor 620 that has the semiconductor structures 625 as its channel region.

The two transistors 610 and 620 may be of opposite types. In embodiments where the transistor 610 is an N-type transistor and the transistor 620 is a P-type transistor, an example of the gate electrode 613 may be the conductive structure 313 in FIG. 3, and an example of the gate electrode 623 may include the conductive structures 323 and 325 in FIG. 3. In embodiments where the transistor 610 is a P-type transistor and the transistor 620 is an N-type transistor, an example of the gate electrode 613 may include the conductive structures 323 and 325 in FIG. 3, and an example of the gate electrode 623 may be the conductive structure 313 in FIG. 3. The transistor 610 or 620 may include a source region and a drain region (not shown in FIG. 6E), and the channel region may be between the source region and drain region in a direction along the X axis. Other components of the transistors 610 and 620 may also be formed.

FIGS. 7A-7B are top views of a wafer 2000 and dies 2002, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 8. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs with dielectric cuts at N-P boundaries as described herein). After the fabrication of the semiconductor product is complete, the wafer 2000 may undergo a singulation process in which each of the dies 2002 is separated from one another to provide discrete “chips” of the semiconductor product. In particular, devices with dielectric cuts at N-P boundaries as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 8 is a side, cross-sectional view of an example IC package 2200 that may include one or more IC devices with dielectric cuts at N-P boundaries, according to some embodiments of the disclosure. In some embodiments, the IC package 2200 may be a system-in-package (SiP).

As shown in FIG. 8, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

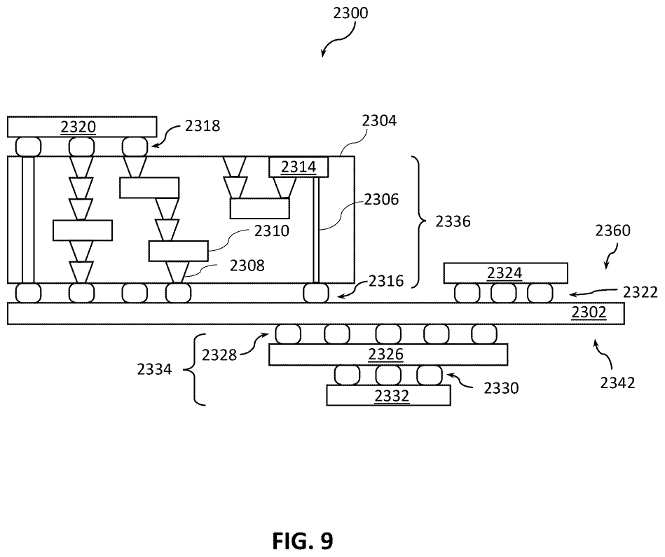

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein and may include any of the embodiments of an IC device with a dielectric cut at an N-P boundary. In embodiments in which the IC package 2200 includes multiple dies 2256, the IC package 2200 may be referred to as a multi-chip package. Importantly, even in such embodiments of a multi-chip packaging (MCP) implementation of the IC package 2200, one or more IC devices with dielectric cuts at N-P boundaries may be provided in a single chip, in accordance with any of the embodiments described herein. The dies 2256 may include circuitry to perform any desired functionality. For example, one or more of the dies 2256 may be ESD protection dies, including one or more IC devices with dielectric cuts at N-P boundaries as described herein, one or more of the dies 2256 may be logic dies (e.g., silicon-based dies), one or more of the dies 2256 may be memory dies (e.g., high bandwidth memory), etc. In some embodiments, any of the dies 2256 may include or otherwise be associated with one or more components with dielectric cuts at N-P boundaries, e.g., as discussed above; in some embodiments, at least some of the dies 2256 may not include any III-N diodes with n-doped wells and capping layers.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC devices with dielectric cuts at N-P boundaries, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with dielectric cuts at N-P boundaries in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more components with dielectric cuts at N-P boundaries in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7B), an IC device (e.g., the IC devices described above), or any other suitable component. In particular, the IC package 2320 may include one or more devices with dielectric cuts at N-P boundaries as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices with dielectric cuts at N-P boundaries as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

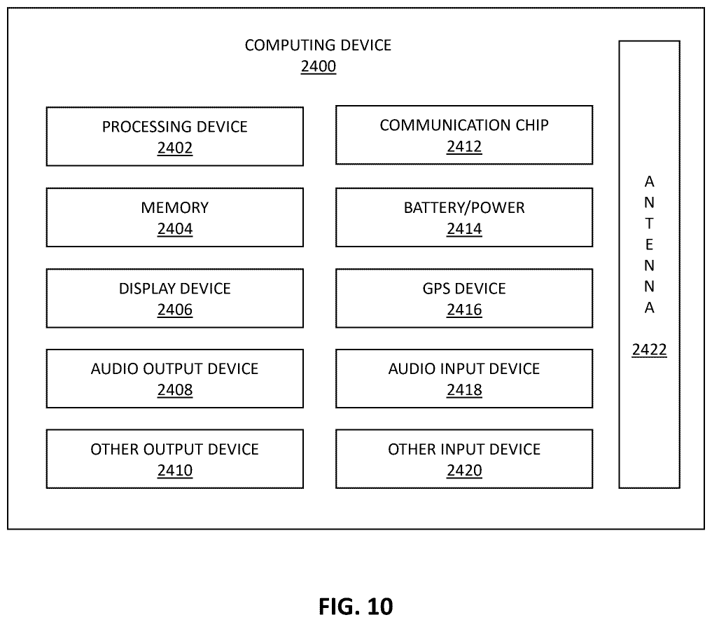

FIG. 10 is a block diagram of an example computing device 2400 that may include one or more components with one or more IC devices with dielectric cuts at N-P boundaries, according to some embodiments of the disclosure. For example, any suitable ones of the components of the computing device 2400 may include a die (e.g., the die 2002 of FIG. 7B) including or associated with devices with dielectric cuts at N-P boundaries, according to some embodiments of the disclosure. Any of the components of the computing device 2400 may include an IC device with a dielectric cut at an N-P boundary (e.g., any embodiment of the IC devices described above in conjunction with FIGS. 1, 2, 4, 5A-5E, and 6A-6G) and/or an IC package (e.g., the IC package 2200 of FIG. 8). Any of the components of the computing device 2400 may include an IC device assembly (e.g., the IC device assembly 2300 of FIG. 9).

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices with dielectric cuts at N-P boundaries as described herein may be particularly advantageous for use as part of ESD circuits protecting power amplifiers, low-noise amplifiers, filters (including arrays of filters and filter banks), switches, or other active components. In some embodiments, IC devices with dielectric cuts at N-P boundaries as described herein may be used in PMICs, e.g., as a rectifying diode for large currents. In some embodiments, IC devices with dielectric cuts at N-P boundaries as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a first semiconductor structure including a P-type semiconductor material; a second semiconductor structure including an N-type semiconductor material; a first dielectric structure surrounding at least part of the first semiconductor structure; a second dielectric structure surrounding at least part of the second semiconductor structure; and a third dielectric structure between the first dielectric structure and the second dielectric structure, in which a dielectric material in the first dielectric structure and the second dielectric structure has a higher dielectric constant than a dielectric material in the third dielectric structure.

Example 2 provides the IC device according to example 1, further including an N-type transistor including the first semiconductor structure; and a P-type transistor including the second semiconductor structure.

Example 3 provides the IC device according to example 2, in which: the third dielectric structure is between the first dielectric structure and the second dielectric structure in a first direction, the N-type transistor includes a first gate electrode over at least part of the first dielectric structure in a second direction that is perpendicular to the first direction, and the P-type transistor includes a second gate electrode over at least part of the second dielectric structure in the second direction.

Example 4 provides the IC device according to example 3, in which the first gate electrode contacts the second gate electrode, and the first gate electrode has a different work function from the second gate electrode.

Example 5 provides the IC device according to any one of examples 1-4, in which the third dielectric structure is between the first dielectric structure and the second dielectric structure in a direction, and a dimension of the third dielectric structure along the direction is in a range from approximately 40 nanometers to approximately 50 nanometers.

Example 6 provides the IC device according to any one of examples 1-5, in which a dielectric constant of the dielectric material in the first dielectric structure and the second dielectric structure is above 3.9, and a dielectric constant of the dielectric material in the third dielectric structure is below 3.9.

Example 7 provides the IC device according to any one of examples 1-6, further including a third semiconductor structure parallel to the first semiconductor structure and at least partially surrounded by the first dielectric structure, the third semiconductor structure includes the P-type semiconductor material; and a fourth semiconductor structure parallel to the second semiconductor structure and at least partially surrounded by the second dielectric structure, the fourth semiconductor structure includes the N-type semiconductor material.

Example 8 provides an IC device, including a first transistor including a P-type semiconductor region, a first dielectric structure surrounding at least part of the P-type semiconductor region, and a first gate electrode over at least part of the first dielectric structure; a second transistor including an N-type semiconductor region, a second dielectric structure surrounding at least part of the N-type semiconductor region, and a second gate electrode over at least part of the second dielectric structure; and a dielectric material between the first dielectric structure and the second dielectric structure, in which the first dielectric structure and the second dielectric structure include a dielectric material that is different from the dielectric material between the first dielectric structure and the second dielectric structure.

Example 9 provides the IC device according to example 8, in which: the P-type semiconductor region includes a first group of semiconductor structures, the N-type semiconductor region includes a second group of semiconductor structures, and a semiconductor structure in the first group or the second group is a nanoribbon.

Example 10 provides the IC device according to example 8 or 9, in which the first transistor includes an N-type source region and an N-type drain region, and the P-type semiconductor region is between the N-type source region and an N-type drain region.

Example 11 provides the IC device according to any one of examples 8-10, in which the second transistor includes a P-type source region and a P-type drain region, and the N-type semiconductor region is between the P-type source region and a P-type drain region.

Example 12 provides the IC device according to any one of examples 8-11, in which the dielectric material in the first dielectric structure and the second dielectric structure has a different dielectric constant from the dielectric material between the first dielectric structure and the second dielectric structure.

Example 13 provides the IC device any one of examples 8-12, in which the dielectric material in the first dielectric structure and the second dielectric structure has a dielectric constant that is higher than a dielectric constant of silicon dioxide.

Example 14 provides the IC device according to any one of examples 8-13, in which the dielectric material between the first dielectric structure and the second dielectric structure has a dielectric constant that is lower than a dielectric constant of silicon dioxide.

Example 15 provides a method of forming an IC device, the method including providing a first dielectric structure that includes a first dielectric material, the first dielectric structure surrounding a P-type semiconductor region and an N-type semiconductor region; removing a portion of the first dielectric structure to form a second dielectric structure surrounding the P-type semiconductor region, a third dielectric structure surrounding the N-type semiconductor region, and an opening region between the second dielectric structure and the third dielectric structure; forming a fourth dielectric structure in the opening region with a second dielectric material, in which the second dielectric material has a lower dielectric constant than the first dielectric material; forming a first electrode over the second dielectric structure; and forming a second electrode over the third dielectric structure.

Example 16 provides the method according to example 15, in which a dimension of the opening region is in a range from approximately 40 nanometers to approximately 50.

Example 17 provides the method according to example 15 or 16, in which the second electrode has a different work function from the first electrode.

Example 18 provides the method according to any one of examples 15-17, in which the P-type semiconductor region is a channel region of an N-type transistor, and the N-type semiconductor region is a channel region of a P-type transistor.

Example 19 provides the method according to example 17, in which a dielectric constant of the first dielectric material is above 3.9, and a dielectric constant of the second dielectric material is below 3.9.

Example 20 provides the method according to any one of examples 15-19, in which: the P-type semiconductor region includes a first group of semiconductor structures, the N-type semiconductor region includes a second group of semiconductor structures, and a semiconductor structure in the first group or the second group is a nanoribbon.

Example 21 provides an IC package, including the IC device according to any one of examples 1-20; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-20 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-20 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides processes for forming the IC device according to any one of claims 1-20.

Example 35 provides processes for forming the IC package according to any one of the claims 21-23.

Example 36 provides processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a first semiconductor structure comprising a P-type semiconductor material;
a second semiconductor structure comprising an N-type semiconductor material;
a first dielectric structure surrounding at least part of the first semiconductor structure;
a second dielectric structure surrounding at least part of the second semiconductor structure; and
a third dielectric structure between the first dielectric structure and the second dielectric structure,
wherein a dielectric material in the first dielectric structure and the second dielectric structure has a higher dielectric constant than a dielectric material in the third dielectric structure.

2. The IC device according to claim 1, further comprising:
an N-type transistor comprising the first semiconductor structure; and
a P-type transistor comprising the second semiconductor structure.

3. The IC device according to claim 2, wherein:
the third dielectric structure is between the first dielectric structure and the second dielectric structure in a first direction,
the N-type transistor comprises a first gate electrode over at least part of the first dielectric structure in a second direction that is perpendicular to the first direction, and
the P-type transistor comprises a second gate electrode over at least part of the second dielectric structure in the second direction.

4. The IC device according to claim 3, wherein the first gate electrode contacts the second gate electrode, and the first gate electrode has a different work function from the second gate electrode.

5. The IC device according to claim 1, wherein the third dielectric structure is between the first dielectric structure and the second dielectric structure in a direction, and a dimension of the third dielectric structure along the direction is in a range from approximately 40 nanometers to approximately 50 nanometers.

6. The IC device according to claim 1, wherein a dielectric constant of the dielectric material in the first dielectric structure and the second dielectric structure is above 3.9, and a dielectric constant of the dielectric material in the third dielectric structure is below 3.9.

7. The IC device according to claim 1, further comprising:
a third semiconductor structure parallel to the first semiconductor structure and at least partially surrounded by the first dielectric structure, the third semiconductor structure comprises the P-type semiconductor material; and
a fourth semiconductor structure parallel to the second semiconductor structure and at least partially surrounded by the second dielectric structure, the fourth semiconductor structure comprises the N-type semiconductor material.

8. An integrated circuit (IC) device, comprising:
a first transistor comprising a P-type semiconductor region, a first dielectric structure surrounding at least part of the P-type semiconductor region, and a first gate electrode over at least part of the first dielectric structure;
a second transistor comprising an N-type semiconductor region, a second dielectric structure surrounding at least part of the N-type semiconductor region, and a second gate electrode over at least part of the second dielectric structure; and
a dielectric material between the first dielectric structure and the second dielectric structure,
wherein the first dielectric structure and the second dielectric structure include a dielectric material that is different from the dielectric material between the first dielectric structure and the second dielectric structure.

9. The IC device according to claim 8, wherein:
the P-type semiconductor region comprises a first group of semiconductor structures,
the N-type semiconductor region comprises a second group of semiconductor structures, and
a semiconductor structure in the first group or the second group is a nanoribbon.

10. The IC device according to claim 8, wherein the first transistor comprises an N-type source region and an N-type drain region, and the P-type semiconductor region is between the N-type source region and an N-type drain region.

11. The IC device according to claim 8, wherein the second transistor comprises a P-type source region and a P-type drain region, and the N-type semiconductor region is between the P-type source region and a P-type drain region.

12. The IC device according to claim 8, wherein the dielectric material in the first dielectric structure and the second dielectric structure has a different dielectric constant from the dielectric material between the first dielectric structure and the second dielectric structure.

13. The IC device according to claim 8, wherein the dielectric material in the first dielectric structure and the second dielectric structure has a dielectric constant that is higher than a dielectric constant of silicon dioxide.

14. The IC device according to claim 8, wherein the dielectric material between the first dielectric structure and the second dielectric structure has a dielectric constant that is lower than a dielectric constant of silicon dioxide.

15. A method of forming an integrated circuit (IC) device, the method comprising:
providing a first dielectric structure that includes a first dielectric material, the first dielectric structure surrounding a P-type semiconductor region and an N-type semiconductor region;
removing a portion of the first dielectric structure to form a second dielectric structure surrounding the P-type semiconductor region, a third dielectric structure surrounding the N-type semiconductor region, and an opening region between the second dielectric structure and the third dielectric structure;
forming a fourth dielectric structure in the opening region with a second dielectric material, wherein the second dielectric material has a lower dielectric constant than the first dielectric material;
forming a first electrode over the second dielectric structure; and
forming a second electrode over the third dielectric structure.

16. The method according to claim 15, wherein a dimension of the opening region is in a range from approximately 40 nanometers to approximately 50.

17. The method according to claim 15, wherein the second electrode has a different work function from the first electrode.

18. The method according to claim 15, wherein the P-type semiconductor region is a channel region of an N-type transistor, and the N-type semiconductor region is a channel region of a P-type transistor.

19. The method according to claim 17, wherein a dielectric constant of the first dielectric material is above 3.9, and a dielectric constant of the second dielectric material is below 3.9.

20. The method according to claim 15, wherein:
the P-type semiconductor region comprises a first group of semiconductor structures,
the N-type semiconductor region comprises a second group of semiconductor structures, and
a semiconductor structure in the first group or the second group is a nanoribbon.
